(19) United States
(12) Patent Application Publication
(10) Pub. No.: US 2025/0233033 A1
(43) Pub. Date: Jul. 17, 2025

(54) PACKAGING STRUCTURE AND PREPARING METHOD THEREOF

(71) Applicant: TRIPLE WIN TECHNOLOGY (SHENZHEN) CO. LTD., Shenzhen (CN)

(72) Inventor: HUNG-TA LI, New Taipei (TW)

(21) Appl. No.: 19/014,501

(22) Filed: Jan. 9, 2025

(30) Foreign Application Priority Data
Jan. 16, 2024 (CN) 202410064830.4

(51) Int. Cl. H01L 23/29; H01L 21/56; H01L 21/768; H01L 23/00; H01L 23/31; H01L 23/498; H01L 25/18

(52) U.S. Cl. CPC H01L 23/293; H01L 21/568; H01L 21/76877; H01L 23/3128; H01L 23/49838; H01L 23/562; H01L 25/18; H01L 24/05; H01L 24/08; H01L 2224/05624; H01L 2224/08225; H01L 2924/1461

(57) ABSTRACT

A packaging structure and a preparing method are provided. The structure includes a first packaging body, a second packaging body, a first component embedded in the first packaging body, and a second component embedded in the second packaging body. The first packaging body includes a first surface and a second surface. The first packaging body includes a first conductive structure partially exposed from the second surface, and the first conductive structure is electrically connected to the first component. The second packaging body is formed on the first packaging body and includes a third surface and a fourth surface. The second packaging body includes a second conductive structure partially exposed from the third and fourth surfaces. The second conductive structure exposed from the third surface is electrically connected to the exposed first conductive structure. The second conductive structure exposed from the fourth surface is electrically connected to the second component.

### FIELD

The subject matter herein generally relates to semiconductor packages, and more particularly, to a packaging structure and a preparing method of the packaging structure.

### BACKGROUND

Package on Package (POP) technology is widely used in semiconductor industries. The POP technology is a 3D system packaging technology that integrates various chips with a similar size but different functions together, which may improve the performance of the chips while saving the spaces occupied by the chips.

In the POP technology, the chips may be active components such as logic chips, storage chips, image sensing chips, or microelectromechanical chips. The chips may also be passive components such as resistors, capacitors, or inductors. The various chips are first integrated into System In Package (SIP) products based on required functions. Then, the package products with different functions are stacked and bonded together by solder balls to form an integrated packaging structure. However, when the solder balls are used for packaging, different package products may have different state under the high temperature of a reflow soldering process, such that the package products may bent in different directions after the reflow soldering process, which may lead to poor soldering. At the same time, when the solder balls are used for packaging, the solder ball itself has a certain diameter, and a certain distance may also be required between adjacent solder balls to avoid short circuit after the reflow soldering process caused by bridging between adjacent solder balls. Such the diameter and distance limit the quantity of input/output ports (IO pins) in the packaging structure. Improvements in the art are desired.

### BRIEF DESCRIPTION OF THE DRAWINGS

FIG. 1 is a diagrammatic view of a packaging structure according to an embodiment of the present disclosure.

FIG. 2A is a diagrammatic view showing a first component and a first plastic preform formed on a carrier board.

FIG. 2B is a diagrammatic view showing the first plastic preform shown in FIG. 2A solidified to form a first block.

FIG. 2C is a diagrammatic view showing a first hole formed in the first block shown in FIG. 2B.

FIG. 3 is a diagrammatic view showing a first conductive portion formed in the first hole shown in FIG. 2C.

FIG. 4 is a top view of FIG. 3.

FIG. 5A is a diagrammatic view showing a second plastic preform formed on the first block shown in FIG. 3.

FIG. 5B is a diagrammatic view showing the second plastic preform shown in FIG. 5A solidified to form a second block.

FIG. 6 is a diagrammatic view showing a first trench formed in the second block shown in FIG. 5B.

FIG. 7A is a diagrammatic view showing a second conductive portion formed in the first trench shown in FIG. 6.

FIG. 7B is a top view of FIG. 7A.

FIG. 8 is a diagrammatic view showing a third component formed on the second block shown in FIG. 7A.

FIG. 9 is a diagrammatic view showing a lower plastic block formed on a first plastic encapsulating body shown in FIG. 8.

FIG. 10 is a diagrammatic view showing a third conductive portion formed in the lower plastic block shown in FIG. 9.

FIG. 11A is a diagrammatic view showing a second component and an upper plastic block formed on a support plate.

FIG. 11B is a diagrammatic view showing a connecting channel formed in the upper plastic block shown in FIG. 11A.

FIG. 11C is a diagrammatic view showing a fourth conductive portion formed in the connecting channel shown in FIG. 11B, and the support plate shown in FIG. 11B removed.

FIG. 11D is a diagrammatic view showing a groove formed in the third block shown in FIG. 11C and an eighth conductive portion formed in the groove.

FIG. 12 is a diagrammatic view showing an intermediate body shown in FIG. 11C and the lower plastic block shown in FIG. 10 assembled together.

FIG. 13 is a diagrammatic view showing the carrier board shown in FIG. 12 removed.

FIG. 14 is a diagrammatic view of a packaging structure according to another embodiment of the present disclosure.

FIG. 15 is a diagrammatic view showing the second component formed on the plastic encapsulating body shown in FIG. 7A according to another embodiment.

FIG. 16 is a diagrammatic view showing a second plastic encapsulating body on the second block shown in FIG. 15.

FIG. 17 is a diagrammatic view showing a protective cover formed on the second plastic encapsulating body shown in FIG. 16.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Implementations of the present disclosure will now be described, by way of embodiments, with reference to the above figures. The embodiments are obviously a portion but not all of the embodiments of the present disclosure.

When a component is fixed to another component, the two components may be directly fixed to each other or indirectly fixed to each other or through an intermediate medium. When a component is located on another component, the component may be directly located on the another component, or an intermediate medium may exist therebetween.

Unless otherwise defined, the technical terms used in the present disclosure have the same meanings as those commonly understood by those skilled in the art. The terms used in the present disclosure are for describing specific embodiments but not intended to limit the scope of present disclosure.

### FIRST EMBODIMENT

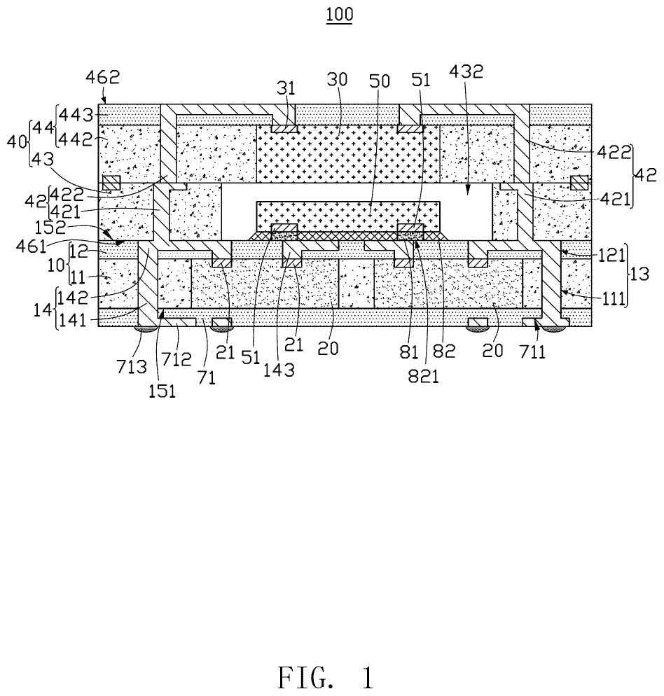

Referring to FIG. 1, a packaging structure 100 is provided according to an embodiment of the present disclosure. The packaging structure 100 includes a first plastic encapsulating body 10, a first component 20, a second component 30, and a second plastic encapsulating body 40. There are a number of first conductive structures 14 formed in the first plastic encapsulating body 10, and a portion of each of the first conductive structures 14 is exposed from the first plastic encapsulating body 10. The first component 20 is embedded in the first plastic encapsulating body 10. The exposed portion of the first conductive structure 14 is further electrically connected to the first component 20. In at least one embodiment, the first plastic encapsulating body 10 includes a first surface 151 and a second surface 152 opposite to each other. A portion of each of the first conductive structures 14 is exposed from the second surface 152, and the portion of the first conductive structure 14 exposed from the second surface 152 is electrically connected to the first component 20.

The second plastic encapsulating body 40 is located on the first plastic encapsulating body 10. There are a number of second conductive structures 42 located in the second plastic encapsulating body 40. The second plastic encapsulating body 40 includes a third surface 461 facing the second surface 152 and a fourth surface 462 opposite to the third surface 461. A portion of each of the second conductive structures 42 is exposed from the third surface 461 and the fourth surface 462. The portion of the second conductive structure 42 exposed from the third surface 461 is electrically connected to the portion of the first conductive structure 14 exposed from the second surface 152. The second component 30 is embedded in the second plastic encapsulating body 40. The portion of the second conductive structure 42 exposed from the fourth surface 462 is further electrically connected to the second component 30. Therefore, the first component 20 and the second component 30 are electrically connected to each other through the first conductive structure 14 and the second conductive structure 42.

In the above embodiment, the first conductive structure 14 and the second conductive structure 42 are directly and electrically connected to each other, and the first component 20 and the second component 30 are electrically connected to each other through the first conductive structure 14 and the second conductive structure 42. Compared to using solder balls for packaging, the present disclosure omits the solder balls at the connection area between the first conductive structure 14 and the second conductive structure 42, thereby reducing the number of reflow soldering steps during the packaging process and reducing the bending of the first component 20 and the second component 30 during the electrical connection between the first conductive structure 14 and the second conductive structure 42. Since the quantity of input/output ports in the packaging structure 100 is not limited by the spacing between the solder balls, it is also possible to increase the quantity of the input/output ports in the packaging structure 100.

In some embodiments, the second component 30 has at least one first electrical connector 31. The first component 20 has at least one second electrical connector 21. The second conductive structure 42 is electrically connected to the second component 30 through the first electrical connector 31. The first conductive structure 14 is electrically connected to the first component 20 through the second electrical connector 21. For example, the second component 30 includes at least two first electrical connectors 31, which are electrically connected to two second conductive structures 42, thereby achieving the electrical connection between the second component 30 and the first component 20. In other embodiments, the second conductive structure 42 may also be electrically connected to electrodes of the second component 30 to achieve the electrical connection between the second component 30 and the first component 20.

In some embodiments, the first electrical connector 31 and the second electrical connector 21 may be solder pads, for example, aluminum pads. The first conductive structure 14 and the second conductive structure 42 may be columnar structures. However, the positions and shapes of the first conductive structure 14 and the second conductive structure 42 in the present disclosure may also be varied according to needs.

Referring to FIG. 1, in some embodiments, the first plastic encapsulating body 10 includes a first block 11 and a second block 12 formed on the first block 11. The first component 20 is embedded in the first block 11. A surface of the first block 11 away from the second block 12 is the first surface 151, and a surface of the second block 12 away from the first block 11 is the second surface 152. In some embodiments, there may be a number of first components 20 embedded in the first plastic encapsulating body 10. The embodiment takes two first components 20 as an example, and the two first components 20 are embedded in the first block 11. Each of the two first components 20 is electrically connected to one of the first conductive structures 14 through a similar manner. In the following description, two first conductive structure 14 connecting to two first components 20 are illustrated for example.

The first conductive structure 14 includes a first conductive portion 141 located in the first block 11 and a second conductive portion 142 located in the second block 12. The direction from the second encapsulating body 40 to the first encapsulating body 10 is defined as a first direction. The first conductive portion 141 extends through the first block 11 along the first direction of the packaging structure 100. The first conductive portion 141 is exposed from the first block 11. One end of the first conductive portion 141 is electrically connected to the second conductive portion 142, and another end of the first conductive portion 141 is exposed from the first surface 151 for connecting to an external device (not shown). The second conductive portion 142 extends at least along the first direction of the packaging structure 100 and along a second direction perpendicular to the first direction. Two ends of the second conductive portion 142 extend toward the first block 11 and the first component 20, respectively. Specifically, one end of the second conductive portion 142 extends toward and is connected to the second electrical connector 21, and another end of the second conductive portion 142 is electrically connected to the first conductive portion 141, thereby achieving the electrical connection between the first conductive portion 141 and the first component 20 through the second conductive portion 142.

The first conductive structure 14 further includes two fifth conductive portions 143, which are located in the second block 12. One end of the fifth conductive portion 143 extends to another second electrical connector 21 of the first component 20, and another end of the fifth conductive portion 143 is exposed from the second block 12 for connecting to other devices.

The second conductive portions 142 and the fifth conductive portions 143 are embedded in the second block 12, and cooperatively form a circuit layer through a redistribution layer (RDL) process. The position and shape of the second conductive portions 142 and the fifth conductive portions 143 in the second block 12 may be adjusted. For example, at least a portion of the second conductive portion 142 may be U-shape, with one end of the second conductive portion 142 being electrically connected to the second electrical connector 21, and another end of the second conductive portion 142 being electrically connected to the first conductive portion 141.

In the above packaging structure 100, at least the first conductive structure 14 forms the redistribution layer in the first plastic encapsulating body 10, such that the first plastic encapsulating body 10 and the first conductive structure 14 may cooperatively form a circuit board that may be used to replace an existing circuit board in a packaging structure.

In some embodiments, each of the first component 20 and the second component 30 may be an active component or a passive component. The active component includes a logic chip, a storage chip, an image sensing chip, or a microelectromechanical chip. The passive component includes a resistor, a capacitor, or an inductor.

Referring to FIG. 1, in some embodiments, the second plastic encapsulating body 40 includes a lower plastic block 43 and an upper plastic block 44 located on the lower plastic block 43. The lower plastic block 43 is located on the second block 12. A surface of the lower plastic block 43 away from the upper plastic block 44 is the third surface 461, and a surface of the upper plastic block 44 away from the lower plastic block 43 is the fourth surface 462. The second component 30 is embedded in the upper plastic block 44, and the first electrical connector 31 is located on a surface of the second component 30 away from the lower plastic block 43. The second conductive structure 42 includes a third conductive portion 421 located in the lower plastic block 43 and a fourth conductive portion 422 located in the upper plastic block 44. A portion of the fourth conductive portion 422 is exposed from a surface of the lower plastic block 43 away from the upper plastic block 44. The exposed portion of the fourth conductive portion 422 is electrically connected to the third conductive portion 421. A portion of the third conductive portion 421 is exposed from the third surface 461. The exposed portion of the third conductive portion 421 is electrically connected to the second conductive portion 142. Another end of the fourth conductive portion 422 is electrically connected to the first electrical connector 31 of the second component 30. The lower plastic block 43 and the upper plastic block 44 are separately made and then fixed to each other by wafer bonding technology. The third conductive portion 421 and the fourth conductive portion 422 are fixed to each other by metal bonding technology. Since the lower plastic block 43 and the upper plastic block 44 are separately made, the preparation and assembly of the lower plastic block 43 and the upper plastic block 44 are facilitated during the packaging process to obtain the packaging structure 100.

For example, the lower plastic block 43 is first formed on the second block 12, and the upper plastic block 44 containing the second component 30 is bonded to the lower plastic block 43. Through the metal bonding technology, the third conductive portion 421 and the fourth conductive portion 422 are fixed to each other. The metal bonding may be fusion bonding, metal thermal compression bonding, and eutectic bonding. The fourth conductive portion 422 and the third conductive portion 421 are fixed to each other such as by solder paste for example, and adhesive is filled at the connection area between the lower plastic block 43 and the upper plastic block 44 to improve the bonding strength therebetween and to prevent water and moisture from entering the connection area, thereby improving the reliability.

Referring to FIG. 1, in some embodiments, the lower plastic block 43 defines a cavity 432. The second block 12 and the upper plastic block 44 enclose two opposite sides of the cavity 432, respectively. The packaging structure 100 further includes a third component 50 located on the second block 12. The third component 50 is received in the cavity 432 and electrically connected to the first component 20. Along the first direction, the second component 30 and the third component 50 are spaced from each other. The third component 50 includes at least one third electrical connector 51, which are located on a surface of the third component 50 facing the second block 12. The third electrical connector 51 may be a solder pad, such as an aluminum pad. The third electrical connector 51 is electrically connected to the portion of the fifth conductive portion 143 exposed from the second surface 152. That is, two ends of the fifth conductive portion 143 are electrically connected to the second electrical connector 21 and the third electrical connector 51, respectively, thereby achieving the electrical connection between the first component 20 and the third component 50. The first component 20, the second component 30, and the third component 50 are electrically connected to each other through the first conductive structure 14 and the second conductive structure 42. As such, different components can be integrated and packaged into the packaging structure 100, which may achieve miniaturization of the packaging structure 100 and simplifying the assembly of the packaging structure 100. Furthermore, the lower plastic block 43 serves as a support frame to support the upper plastic block 44, thereby maintaining a gap between the second component 30 and the third component 50. The cavity 432 may be in a vacuum state, which protects the third component 50 from external environmental factors such as temperature, humidity, or gas. The third component 50 may be a MEMS component, such as an accelerometer, a magnetic sensor, and a gyroscope sensor.

In other embodiments, the third component 50 is embedded in the lower plastic block 43, and the lower plastic block 43 is wrapped around the sidewall of the third component 50. That is, there is no hollow cavity inside the lower plastic block 43. By completely encapsulating the third component 50 with the lower plastic block 43, more components may be integrated into the packaging structure 100.

Referring to FIG. 1, there is at least one electrical connecting portion 81 between the third electrical connector 51 and the fifth conductive portion 143. The third electrical connector 5 of the third component 50 is soldered at the fifth conductive portion 143 through the electrical connection portion 81 by flip-chip bonding technology. In some embodiments, a reinforcement layer 82 is further provided between the third electrical connector 51 and the fifth conductive portion 143, and the reinforcement layer 82 defines at least one receiving hole 821. The electrical connecting portion 81 is received in the receiving hole 821. The reinforcement layer 82 is bonded between the third component 50 and the second block 12, which improves the mechanical strength and stability of the electrical connection between the third component 50 and the first component 20, and further disperses the stress at the connection area between the third electrical connector 51 and the second conductive portion 142. The electrical connecting portion 81 may be made of a conductive adhesive or a soldering flux.

Referring to FIG. 1, in some embodiments, a dielectric layer 71 is provided at the surface of the first block 11 away from the second plastic encapsulating body 40. A number of third conductive structures 712 are located in the dielectric layer 71. The third conductive structures 712 cooperatively form a circuit layer through a redistribution layer process. One end of the third conductive structure 712 is electrically connected to the first conductive portion 141. A portion of the third conductive structure 712 is exposed from the bottom surface of the dielectric layer 71. The bottom surface of the dielectric layer 71 is further provided with a number of solder balls 713. The solder balls 713 are electrically connected to the exposed portions of the third conductive structures 712, such that the packaging structure 100 may be electrically connected to the external device through the solder balls 713. The external device may be a processor in a mobile phone, a computer, or a wearable device.

FIGS. 1 to 13 illustrate a preparing method of a packaging structure 100 in accordance with an embodiment. The method is provided by way of embodiments, as there are a variety of ways to carry out the method. The method can begin at step S1.

At step S1, a first component 20 and a first plastic encapsulating body 10 are formed on a carrier board 3, with the first component 20 being embedded in the first plastic encapsulating body 10. A number of first channels 13 are defined in the first plastic encapsulating body 10 (shown in FIG. 1). The first plastic encapsulating body 10 includes a first surface 151 and a second surface 152 opposite to each other. Each of the first channels 13 is exposed from the first surface 151 and the second surface 152. A first conductive structure 14 is formed in each of the first channels 13, and a portion of the first conductive structure 14 is exposed from the second surface 152 and electrically connected to the first component 20.

In some embodiments, the first plastic encapsulating body 10 includes a first block 11 and a second block 12 located on the first block 11. The surface of the first block 11 away from the second block 12 is the first surface 151. The surface of the second block 12 away from the first block 11 is the second surface 152. The first channel 13 includes a first hole 111 defined in the first block 11 and a first trench 121 defined in the second block 12. The first conductive structure 14 includes a first conductive portion 141 located in the first block 11 and a second conductive portion 142 located in the second block 12. The second conductive portion 142 is connected to the first conductive portion 141. In some embodiments, the step S1 may be carried out by following steps.

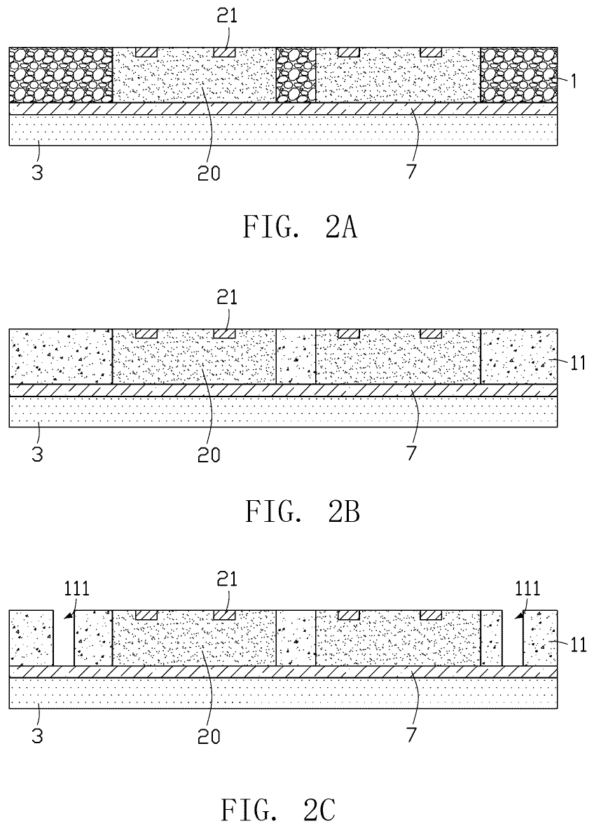

(1) Referring to FIG. 2A, the first component 20 is first placed on the carrier board 3, and a first plastic preform 1 is located on the carrier board 3 and covers the sidewall of the first component 20.

The first component 20 includes at least one second electrical connector 21. The second electrical connector 21 is located on the surface of the first component 20 away from the carrier board 3. The second electrical connector 21 is exposed from the first plastic preform 1. The quantity of the first component 20 may be designed as needed.

There may be an adhesive layer 7 between the carrier board 3 and the first component 20. The first component 20 is fixed on the carrier board 3 through the adhesive layer 7. The carrier board 3 is used to provide support functions and a certain structural strength for the packaging structure 100, thereby facilitating the transportation during the preparation process. In some embodiments, the adhesive layer 7 includes a bonding material layer and a photothermal conversion layer, such that laser beams may be used to irradiate the photothermal conversion layer in the subsequent process to peel off and remove the carrier board 3.

(2) Referring to FIG. 2B, the first plastic preform 1 is solidified to obtain the first block 11.

The first plastic preform 1 may be solidified by heating or UV irradiation. The first plastic preform 1 may be made of a material selected from a group consisting of epoxy resin, polyimide resin, polyimide derivatives, silicone gel, silicon oxide, and any combination thereof. The first block 11 covers the sidewall of the first component 20. The first component 20 is embedded in the first block 11, with the second electrical connector 21 being exposed from the surface of the first block 11 away from the first surface 151. The second electrical connector 21 may be a solder pad.

In some embodiments, a top surface of the first block 11 is ground such as by chemical mechanical grinding, thereby making the top surface of the first block 11 flat and facilitating the subsequent operations.

(3) Referring to FIG. 2C, a number of first holes 111 are defined in the first block 11, and the first holes 111 penetrate the first block 11 along the first direction.

In some embodiments, the first hole 111 may be formed by laser drilling.

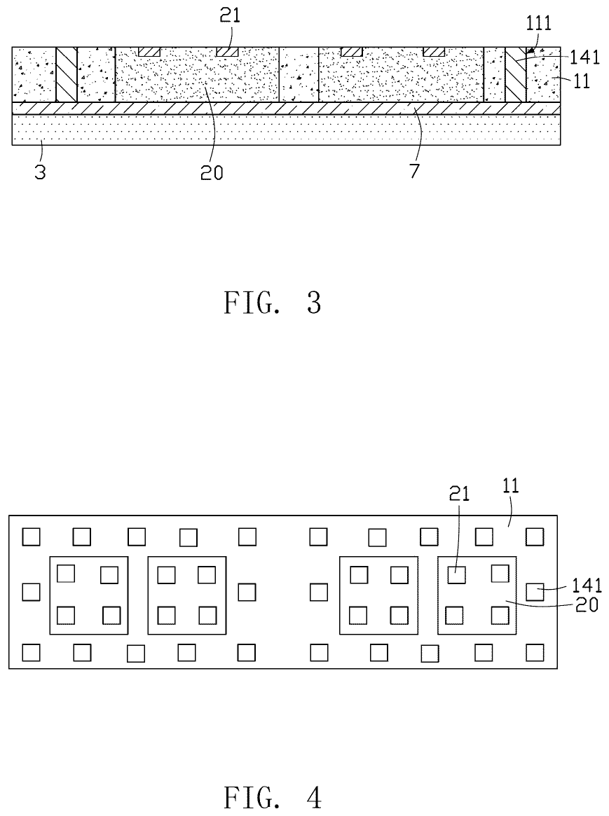

(4) Referring to FIGS. 3 and 4, a conductive material is filled in the first hole 111 to form a first conductive portion 141 in the first hole 111.

In some embodiments, the first conductive portion 141 is filled in the first hole 111, and one end of the first conductive portion 141 is exposed from the first block 11. By drilling holes in the first block 11 and filling the conductive material therein, a circuit layer is formed in the first block 11 by a redistribution layer process. Thus, the first block 11 and the first conductive portions 141 cooperate to form a circuit board.

In some embodiments, the conductive material includes at least one of a conductive ink and a conductive paste. For example, the conductive ink may be free of particles, and may also include at least one element from silver, platinum, gold, copper, nickel, and aluminum.

The solidification of the conductive ink includes a first solidification stage and a second solidification stage after the first solidification stage.

The first solidification stage includes irradiating the conductive ink by ultraviolet beams after the conductive ink is sprayed or injected into the first hole 111, thereby pre-solidifying the conductive ink. At this stage, the ultraviolet irradiation is used to rapidly pre-solidify the conductive ink and prevent the flow of the conductive ink. The ultraviolet irradiation is performed for a few seconds, such as 1 second to 5 seconds.

The second solidification stage includes baking the pre-solidified conductive ink to obtain the first conductive portion 141. After the first solidification stage, the conductive ink is pre-formed on the inner wall of the first hole 111. After the conductive ink is baked at a temperature of 100° C. to 180° C. for a duration of 0.1 h to 3 h, the conductive ink is completely solidified on the inner wall of the first hole 111. The above solidification method may also be used in the subsequent processes. In other embodiments, screen printing technology may also be used to form the conductive ink. In other embodiments, carbon-based conductive ink may also be used as the conductive ink.

The conductive ink may be at least one of nano silver ink, nano silver copper ink, or silver ion ink. In other embodiments, the conductive material may also include a conductive paste, which may be a mixture of noble metal powder and base metal powder, glass powder, and synthetic resin. The conductive paste includes copper paste, gold paste, or nickel paste. The conductive portions may be formed by printing conductive paste through screen printing, exposing the conductive paste, and solidifying the conductive paste.

In other embodiments, the conductive portions may also be formed by filling in the holes with conductive metal material.

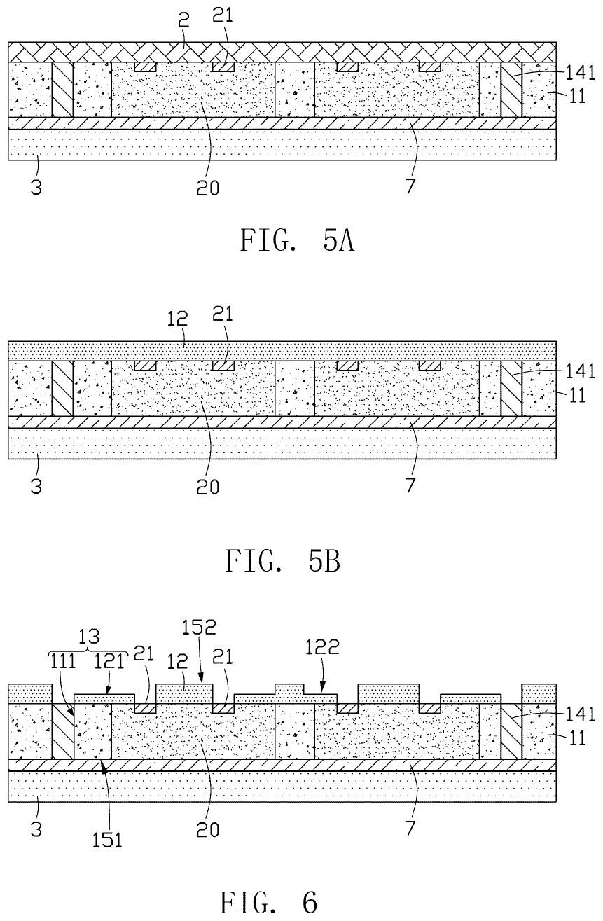

(5) Referring to FIGS. 5A and 5B, a second plastic preform 2 is formed on the first block 11 and the first component 20, and then solidified to obtain the second block 12.

The second plastic preform 2 covers the first block 11 and the first component 20, and the second electrical connector 21 and the first conductive portion 141 are also covered by the second plastic preform 2.

In some embodiments, the first block 11 and the second block 12 may be made of a same material. After the second block 12 is obtained, a top surface of the second block 12 is ground, thereby making the top surface of the second block 12 flat and facilitating the subsequent operations.

(6) Referring to FIG. 6, a number of first trenches 121 and second trenches 122 are defined in the second block 12.

The first trench 121 is recessed from the second surface 152 of the second block 12. The second electrical connector 21 and an end of the first conductive portion 141 are exposed from the first trench 121. Both ends of the first trench 121 pass through the second block 12, such that the first conductive portion 141 and the second electrical connector 21 are exposed at the bottom of the first trench 121. A laser drilling step may be used to form a portion of the first trench 121 on the second block 12, thereby exposing the first conductive portion 141 from the second block 12. Furthermore, the laser drilling step may be repeated to form another portion of the first trench 121 on the second block 12, thereby exposing the second electrical connector 21 from the second block 12. The order of the above two laser drilling steps may also be exchanged.

The second trench 122 is also recessed from the second surface 152. Another second electrical connector 21 is exposed from the second trench 122. One end of the second trench 122 penetrates the second block 12, such that the second electrical connector 21 is exposed from the second block 12.

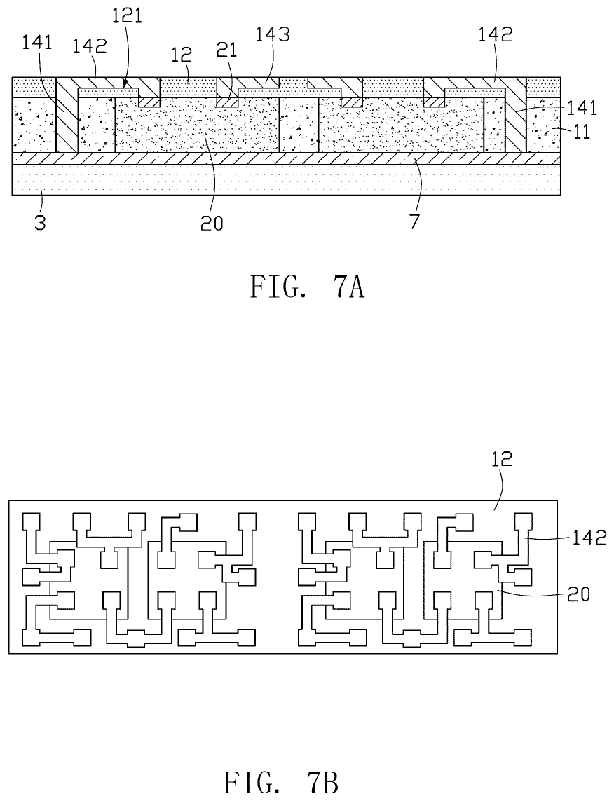

(7) Referring to FIG. 7A, a conductive material is filled in the first trench 121 to form a second conductive portion 142 in the first trench 121. The first conductive portion 141 and the second conductive portion 142 are electrically connected to each other.

The conductive material may also be filled in the second trench 122 to form a fifth conductive portion 143 in the second trench 122. The conductive material may be synchronously filled in the first trench 121 and the second trench 122.

The first conductive portion 141 and the second conductive portion 142 may be made of a same conductive material.

Referring to FIG. 7B, the second conductive portion 142 is formed on the second block 12 and electrically connected to the first component 20. A portion of the second conductive portion 142 is exposed from the second block 12.

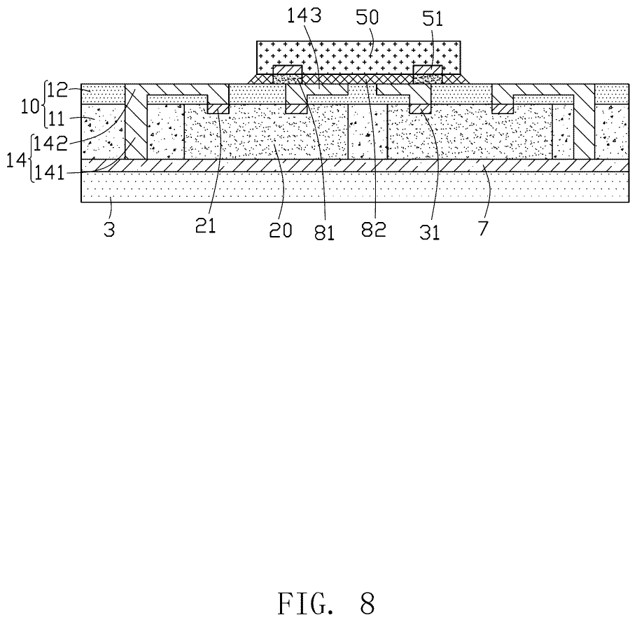

At step S2, referring to FIG. 8, a third component 50 is installed on the first plastic encapsulating body 10. The third component 50 includes a third electrical connector 51. The third electrical connector 51 is electrically connected to the first conductive structure 14.

The third component 50 is soldered on the first conductive structure 14 by flip-chip bonding technology. In some embodiments, the third electrical connector 51 is located on a surface of the third component 50 facing the second block 12, and soldered to the fifth conductive portion 143 by flip-chip bonding technology. A conductive adhesive or solder flux may be used to connect the third electrical connector 51 to the fifth conductive portion 143. Afterwards, adhesive is filled between the second block 12 and the third component 50 and solidified to obtain a reinforcement layer 82, which improves the mechanical strength of the connection area between the third component 50 and the second block 12, thereby enhancing the electrical connection stability between the third component 50 and the fifth conductive portion 143.

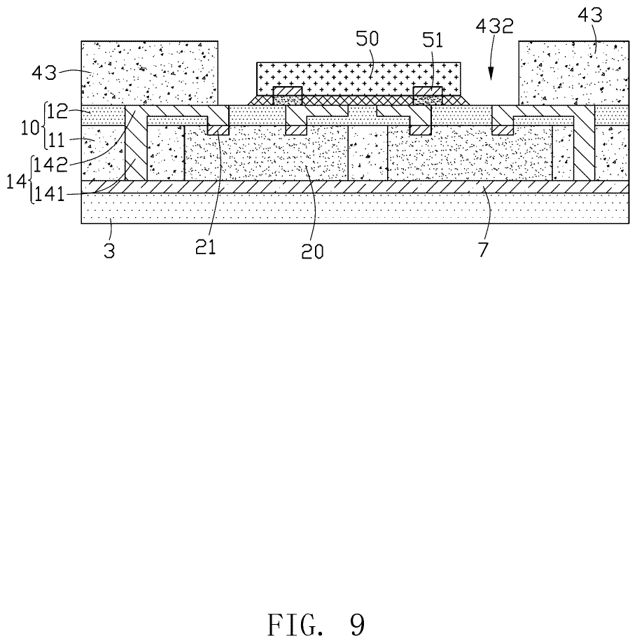

At step S3, referring to FIGS. 9 to 13, a second plastic encapsulating body 40 is formed on the first plastic encapsulating body 10, with a second component 30 being embedded in the second plastic encapsulating body 40. A number of second channels 41 are defined in the second plastic encapsulating body 40, and a conductive material is filled in each of the second channels 41 to form a second conductive structure 42. The second plastic encapsulating body 40 includes a third surface 461 facing the second surface 152 and a fourth surface 462 opposite to the third surface 461.

A portion of the second conductive structure 42 is exposed from the third surface 461, and electrically connected to the portion of the first conductive structure 14 exposed from the second surface 152. A portion of the second conductive structure 42 is exposed from the fourth surface 462, and electrically connected to the second component 30. The first component 20 and the second component 30 are electrically connected to each other through the first conductive structure 14 and the second conductive structure 42.

The second plastic encapsulating body 40 may be formed by solidifying a plastic preform. The second plastic encapsulating body 40 is directly solidified on the second block 12. In some embodiments, the second encapsulating body 40 may include a material selected from a group consisting of epoxy resin, polyimide resin, polyimide derivative, silicone gel, silicon oxide, and any combination thereof. In an embodiment, the second plastic encapsulating body 40 is made of silicone gel.

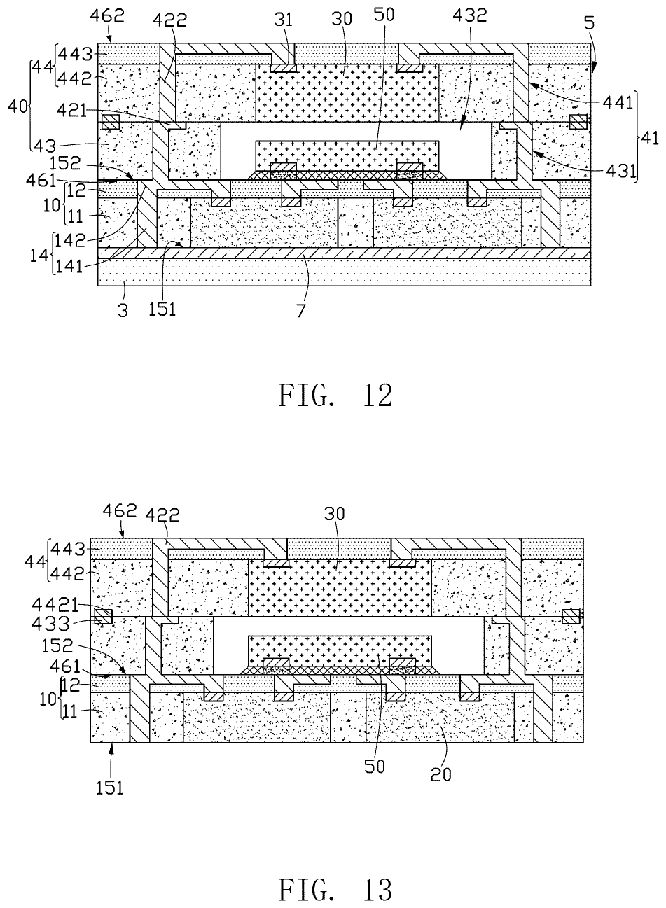

Referring to FIGS. 9 to 11D, the second plastic encapsulating body 40 includes a lower plastic block 43 located on the first plastic encapsulating body 10 and an upper plastic block 44 located on the lower plastic block 43. The surface of the lower plastic block 43 away from the upper plastic block 44 is the third surface 461, and the surface of the upper plastic block 44 away from the lower plastic block 43 is the fourth surface 462. The second component 30 is embedded in the upper plastic block 44. The second conductive structure 42 includes a third conductive portion 421 located in the lower plastic block 43 and a fourth conductive portion 422 located in the upper plastic block 44. The second channel 41 (shown in FIG. 12) includes a second hole 431 defined in the lower plastic block 43 and a connecting channel 441 defined in the upper plastic block 44. Forming the second plastic encapsulating body 40 on the first plastic encapsulating body 10 may be carried out by the following steps.

At step S3-1, referring to FIG. 9, a plastic preform is formed on the second block 12 and solidified to obtain the lower plastic block 43. The lower plastic block 43 defines a cavity 432 in the middle area of the lower plastic block 43. The third component 50 is located in the cavity 432, leaving a gap between the lower plastic block 43 and the third component 50.

In other embodiments, the lower plastic block 43 is wrapped around the sidewall of the third component 50, and the third component 50 is embedded in the lower plastic block 43 (not shown). The top surface of the lower plastic block 43 may be ground to facilitate subsequent bonding of the lower plastic block 43 to the upper plastic block 44.

At step S3-2, referring to FIG. 10, the second hole 431 is defined in the lower plastic block 43, and a conductive material is filled in the second hole 431 to form the third conductive portion 421 in the second hole 431.

The second hole 431 extends through the lower plastic block 43 along the first direction. A portion of the third conductive portion 421 is exposed from the third surface 461 and electrically connected to the second conductive portion 142. Another portion of the second hole 431 is further exposed from a surface of the lower plastic block 43 away from the third surface 461, such that the third conductive portion 421 may also be electrically connected to another device.

In some embodiments, the lower plastic block 43 may also define a groove at the end of the second hole 431 away from the third surface 461. The group communicates with the second hole 431. The groove is designed to increase the surface area of the portion of the third conductive portion 421 exposed from the lower plastic block 43, thereby facilitate subsequent bonding of the fourth conductive portion 422 to the third conductive portion 421.

In some embodiments, another groove is also defined at the surface of the lower plastic block 43 away from the third surface 461. The groove is filled with conductive material to form a seventh conductive portion 433. The seventh conductive portion 433 is exposed from the surface of the lower plastic block 43 away from the third surface 461.

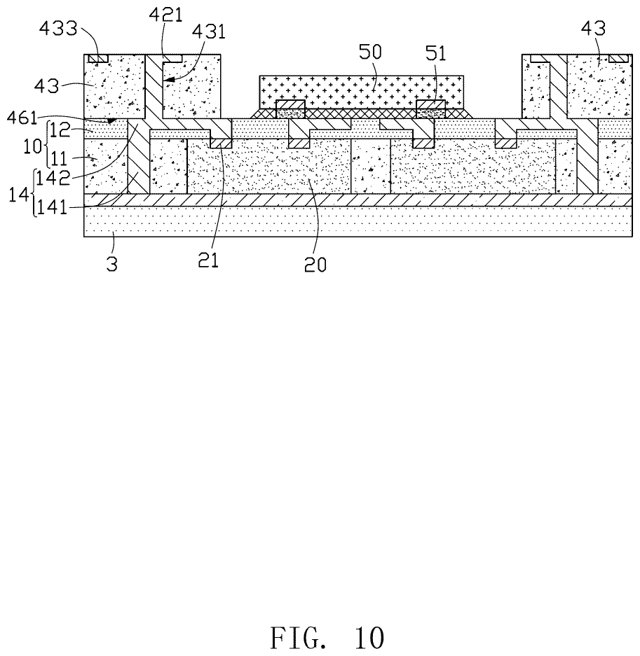

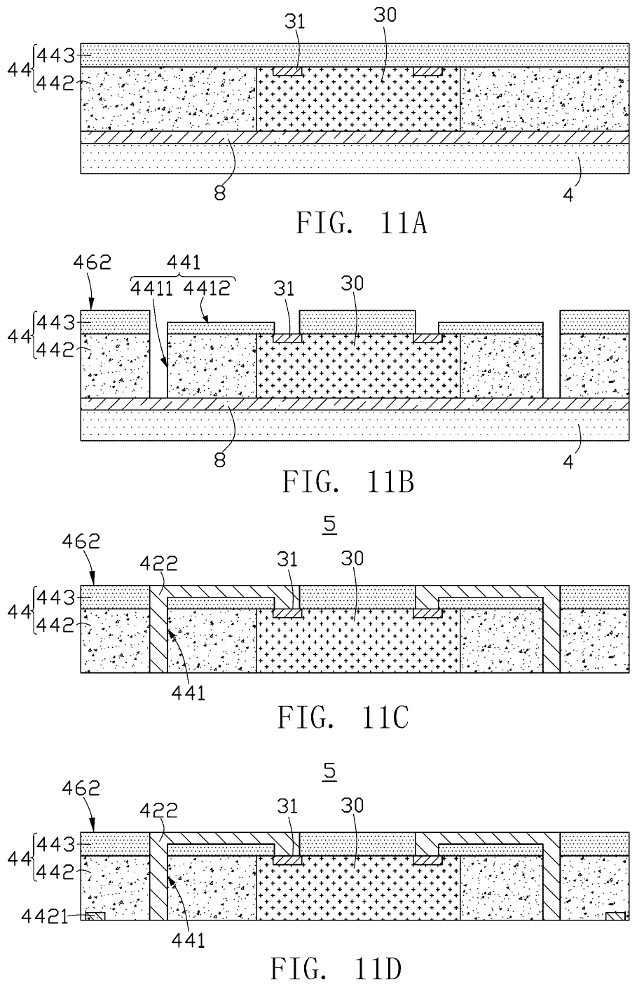

At step S3-3, referring to FIGS. 11A to 11D, an intermediate body 5 is prepared, wherein the step S3-3 may also be included in step S3. The steps S3-3 may be carried out by following steps.

(1) Referring to FIG. 11A, the second component 30 and the upper plastic block 44 are formed on the support plate 4. The second component 30 is embedded in the upper plastic block 44.

The upper plastic block 44 includes a third block 442 and a fourth block 443 located on the third block 442. The second component 30 is embedded in the third block 442. The third block 442 is formed on the support plate 4, and there is also an adhesive layer 8 between the third block 442 and the support plate 4. The third block 442 is bonded to the support plate 4 through the adhesive layer 8. The third block 442 is formed by solidifying a plastic preform. The first electrical connector 31 is located on the surface of the second component 30 away from the support plate 4. After the third block 442 is formed, the fourth block 443 is formed on the third block 442 and the second component 30 by solidifying a plastic preform. The fourth block 443 covers the surface of the second component 30 away from the support plate 4.

(2) Referring to FIG. 11B, a number of connecting channels 441 are defined in the upper plastic block 44.

The support plate 4 and the adhesive layer 8 between the support plate 4 and the third block 442 are removed. The connecting channel 441 extends through the third block 442 and the fourth block 443. The connecting channel 441 further extends along the surface of the fourth block 443 toward the first electrical connector 31.

In some embodiments, the connecting channel 441 includes a third hole 4411 penetrating the third block 442 and a third trench 4412 defined in the fourth block 443. The third hole 4411 penetrates the third block 442. One end of the third trench 4412 communicates with the third hole 4411. The first electrical connector 31 is exposed from another end of the third trench 4412. In some embodiments, the connecting channel 441 may be formed by laser drilling.

In other embodiments, only the support plate 4 is removed, and the adhesive layer 8 is still bonded to the third block 442, which is beneficial for strengthening the connecting strength between the subsequent third block 442 and the second block 12.

(3) Referring to FIG. 11C, a conductive material is filled in the connecting channel 441 to form a fourth conductive portion 422. The support plate 4 is removed to obtain the intermediate body 5.

The conductive material is filled into the third hole 4411 and the third groove 4412 to form the fourth conductive portion 422. The two ends of the fourth conductive portion 422 are exposed from the third block 442 and the fourth block 443, respectively. The portion of the fourth conductive portion 422 located in the third groove 4412 is exposed from the fourth surface 462. One end of the fourth conductive portion 422 extends toward the first electrical connector 31, and is electrically connected to the second component 30 through the first electrical connector 31. Another end of the fourth conductive portion 422 is exposed from the surface of the third block 442 away from the fourth surface 462.

Referring to FIG. 11D, in some embodiments, a groove is also defined at the surface of the third block 442 away from the fourth surface 462. A conductive material is filled in the groove to form an eighth conductive portion 4421.

At step S4, referring to FIG. 12, the intermediate body 5 prepared in step S3 is placed on the lower plastic block 43, and the fourth conductive portion 422 and the third conductive portion 421 are electrically connected to each other. The electrical connection between the first component 20 and the second component 30 is achieved through the electrical connection between the third conductive portion 421 and the second conductive portion 142.

The upper plastic block 44 is formed on the lower plastic block 43 by metal bonding. The third conductive portion 421 and the fourth conductive portion 422 are connected to each other by metal bonding, thereby achieving the electrical connection between the third conductive portion 421 and the fourth conductive portion 422. In an embodiment, the eighth conductive portion 4421 and the seventh conductive portion 433 are also connected to each other by metal bonding, thereby achieving the electrical connection therebetween (shown in FIG. 13).

In some embodiments, an adhesive layer (not shown) is also provided between the intermediate body 5 and the second block 12. The adhesive layer may be formed by solidifying an adhesive, which improves the connection stability between the intermediate body 5 and the second block 12.

At step S5, referring to FIG. 13, the carrier board 3 is removed.

The adhesive layer 7 may also be removed at the same time.

At step S6, referring to FIG. 1, a dielectric layer 71 is formed on the surface of the first plastic encapsulating body 10 away from the second plastic encapsulating body 40. A redistribution layer process is performed at the dielectric layer 71 to obtain the packaging structure 100.

The dielectric layer 71 is provided on the surface of the first encapsulating body 10 away from the second encapsulating body 40. The dielectric layer 71 defines a number of third channels 711. A portion of the third channel 711 extends through the dielectric layer 71, and another portion of the third channel 711 is recessed from the surface of the dielectric layer 71 away from the first plastic encapsulating body 10. The third channel 711 may be a groove. A portion of the groove extends through the dielectric layer 71, and another portion of the groove does not extend through the dielectric layer 71.

A conductive material is filled in the third channel 711 to form a third conductive structure 712 in the third channel 711. A portion of the third conductive structure 712, which is formed in the third channel 711 extending through the dielectric layer 71, is electrically connected to the portion of the first conductive portion 141 exposed from the first surface 151. Another portion of the third conductive structure 712, which is formed in another portion of the third channel 711, is exposed from the surface of the dielectric layer 71 away from the first plastic encapsulating body 10.

A number of solder balls 713 are formed on the surface of the dielectric layer 71 away from the first plastic encapsulating body 10, and each of the solder balls 713 is electrically connected to one third conductive structure 712.

In the preparing method of the packaging structure 100 according to the embodiment, the second plastic encapsulating body 40 is directly formed on the first plastic encapsulating body 10, while also achieving the electrical connection between the first conductive structure 14 and the second conductive structure 42, thereby achieving the electrical connection between the first component 20 and the second component 30. In the above electrical connection process, solder balls are not needed during the reflow soldering process. Thus, the present disclosure may replace the existing reflow soldering process using solder balls (such as tin balls) during the package of the intermediate body 5 and first plastic encapsulating body 10, reducing the use of solder balls, and thus reducing the high-temperature steps and the bending of the packaging structure 100. At the same time, since the quantity of the input/output ports in the packaging structure 100 is not limited by the spacing between the solder balls, it is also possible to increase the number of the input/output ports in the packaging structure 100. The second plastic encapsulating body 40 also serves as a support frame to support the intermediate body 5.

Furthermore, the present disclosure combines the conductive materials into the plastic preform (such as resin preform) to prepare the POP packaging structure. During the preparation process, the first component 20, the second component 30, and the third component 50 are integrated together by plastic encapsulation to form a system-level packaging module. The present disclosure is conducive to the miniaturization of the packaging module. The preparing method is simple, which simplifies the semiconductor process for preparing the packaging module.

### SECOND EMBODIMENT

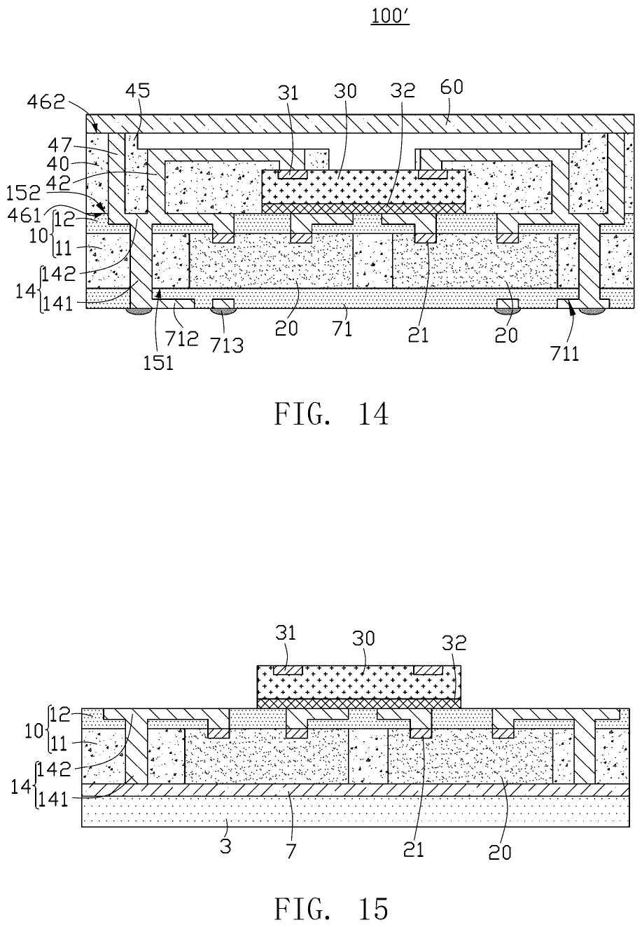

Referring to FIG. 14, a packaging structure 100′ is also provided according to another embodiment of the present disclosure. Different from the above packaging structure 100, the second plastic encapsulating body 40 is a single-layer structure. That is, the second plastic encapsulating body 40 is not composed of the lower plastic block 43 and the upper plastic block 44. The first electrical connector 31 is located on the surface of the second component 30 away from the first plastic encapsulating body 10. The second plastic encapsulating body 40 at least covers the first electrical connector 31. The second conductive structure 42 is electrically connected to the second component 30 through the first electrical connector 31. The second plastic encapsulating body 40 is further wrapped around the sidewall of the second component 30 to achieve plastic encapsulation of the second component 30. A portion of the second conductive structure 42 in the second plastic encapsulating body 40 is exposed from the third surface 461 and electrically connected to the second conductive portion 142. A portion of the second conductive structure 42 is exposed from the fourth surface 462 and electrically connected to the first electrical connector 31. Since the second conductive structure 42 is electrically connected to the second conductive portion 142, the electrical connection between the first component 20 and the second component 30 is achieved.

Referring to FIG. 14, in some embodiments, an adhesive layer 32 is provided between the second component 30 and the second block 12. The second component 30 is bonded to the first plastic encapsulating body 10 through the adhesive layer 32. The adhesive layer 32 may include a DAF adhesive film, a solid crystal film, or a chip bonding film.

Referring to FIG. 14, in some embodiments, a protective cover 60 is further provided on the second plastic encapsulating body 40. Since the protective cover 60 covers the second plastic encapsulating body 40, the protective cover 60 may shields the second conductive structure 42 exposed from the second plastic encapsulating body 40, and further encloses the second component 30 within the packaging structure 100′. The protective cover 60 may include a glass chip, a silicon chip, a sapphire chip, a quartz chip, or a germanium chip.

An edge area of the second plastic encapsulating body 40 away from the third surface 461 protrudes to form an extension block 45. There is also a sixth conductive portion 47 in the second plastic encapsulating body 40, which penetrates the extension block 45 and the second plastic encapsulating body 40. A portion of the sixth conductive portion 47 is exposed from the third surface 461 and electrically connected to the second conductive portion 142. Another portion of the sixth conductive portion 47 is exposed from the extension block 45 for connecting to other devices. The extension block 45 may maintain a certain gap between the protective cover 60 and the portion of the second conductive structure 42 exposed from the second plastic encapsulating body 40, thereby avoiding a direct contact between the protective cover 60 and the second conductive structure 42 and reducing the possibility of short circuits in the packaging structure 100′. The preparing method of the packaging structure 100′ according to the embodiment is the same as the preparing method of the packaging structure 100 in steps S1 and S6, and the other steps are different. The preparing method of the embodiment may further include following steps.

At step S21, referring to FIG. 15, a second component 30 is installed on the first plastic encapsulating body 10, and the first electrical connector 31 is located on the surface of the second component 30 away from the first plastic encapsulating body 10.

The second component 30 may be fixed to the second block 12 through an adhesive layer 32.

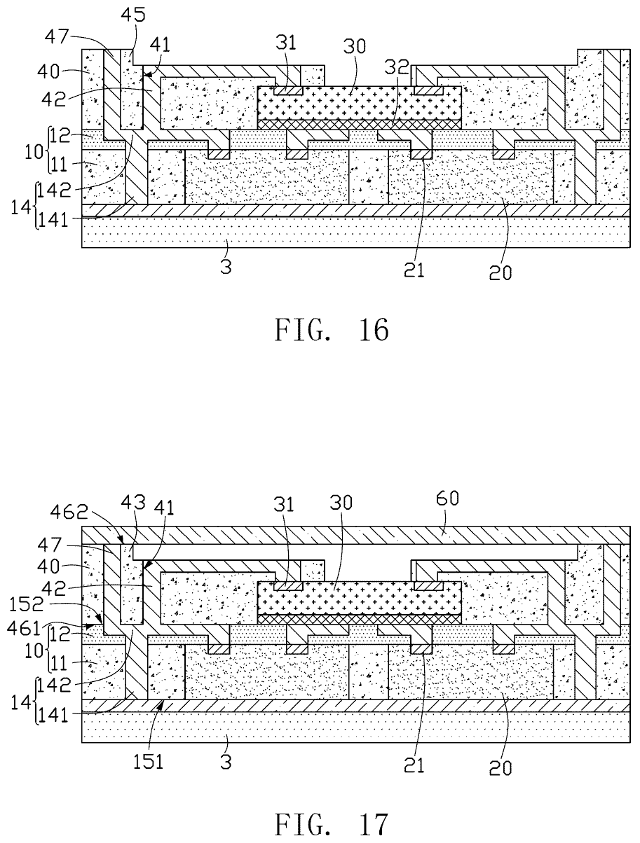

At step S22, referring to FIG. 16, a second plastic encapsulating body 40 is formed on the surface of the first plastic encapsulating body 10, which at least partially covers the surface of the second component 30 away from the first plastic encapsulating body 10. The second plastic encapsulating body 40 covers the first electrical connector 31. A number of second channels 41 are defined in the second plastic encapsulating body 40. A conductive ink is filled in the second channel 41, and then solidified to form a second conductive structure 42 in the second channel 41. The second conductive structure 42 is electrically connected to the first conductive structure 14 and the first electrical connector 31. A sixth conductive portion 47 may also be formed in the step.

The second plastic encapsulating body 40 may be formed by solidifying a plastic preform. During the solidifying process of the conductive ink to form the second conductive structure 42, the second conductive structure 42 is directly and electrically connected to the second conductive portion 142 of the first conductive structure 14, which may replace the existing reflow soldering process using solder balls to electrically connect the second conductive structure 42 to the first conductive structure 14.

At step S23, referring to FIG. 17, a protective cover 60 is installed on the second plastic encapsulating body 40.

The protective cover 60 may be glued to the surface of the second plastic encapsulating body 40 away from the first plastic encapsulating body 10.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. A packaging structure comprising:
a first plastic encapsulating body comprising a first surface and a second surface opposite to each other, the first plastic encapsulating body further comprising a plurality of first conductive structures located in the first plastic encapsulating body, and a portion of each of the plurality of first conductive structures exposed from the second surface;
a first component embedded in the first plastic encapsulating body, and the portion of each of the plurality of first conductive structures exposed from the second surface electrically connected to the first component;
a second plastic encapsulating body formed on the first plastic encapsulating body, the second plastic encapsulating body comprising a third surface facing the second surface and a fourth surface opposite to the third surface, the second plastic encapsulating body further comprising a plurality of second conductive structures located in the second plastic encapsulating body, a portion of each of the plurality of second conductive structures exposed from the third surface and the fourth surface, the portion of each of plurality of second conductive structures exposed from the third surface electrically connected to the portion of a corresponding one of the plurality of first conductive structures exposed from the second surface; and
a second component embedded in the second plastic encapsulating body, and the portion of each of the plurality of second conductive structures exposed from the fourth surface electrically connected to the second component, such that the first component and the second component are electrically connected to each other.

2. The packaging structure according to claim 1, wherein the first plastic encapsulating body comprises a first block and a second block formed on the first block, a surface of the first block away from the second block is the first surface, a surface of the second block away from the first block is the second surface, the first component is embedded in the first block, each of the plurality of first conductive structures comprises a first conductive portion located in the first block and a second conductive portion located in the second block and connected to the first conductive portion, the first conductive portion is exposed from the first surface, and the second conductive portion is exposed from the second surface and electrically connected to the first component.

3. The packaging structure according to claim 1, wherein the second plastic encapsulating body comprises a lower plastic block and an upper plastic block formed on the lower plastic block, the lower plastic block is formed on the first plastic encapsulating body, a surface of the lower plastic block away from the upper plastic block is the third surface, a surface of the upper plastic block away from the lower plastic block is the fourth surface, the second component is embedded in the upper plastic block, each of the plurality of second conductive structures comprises a third conductive portion located in the lower plastic block and a fourth conductive portion located the upper plastic block and connected to the third conductive portion, the third conductive portion is exposed from the third surface and electrically connected to one of the plurality of first conductive structures, and the fourth conductive portion is exposed from the fourth surface and electrically connected to the second component.

4. The packaging structure as claimed in claim 3, wherein the lower plastic block defines a cavity, the first plastic encapsulating body and the upper plastic block enclose two opposite sides of the cavity, respectively; the packaging structure further comprises a third component installed on the second surface, and the third component is received in the cavity and electrically connected to the first component.

5. The packaging structure according to claim 1, further comprising a dielectric layer formed on the first surface and a plurality of third conductive structures located in the dielectric layer, wherein a portion of each of the plurality of third conductive structures is exposed from the dielectric layer and electrically connected to a corresponding one of the plurality of first conductive structures; the packaging structure further comprises a plurality of solder balls formed on the dielectric layer, and the plurality of solder balls is electrically connected to the plurality of third conductive structures.

6. The packaging structure according to claim 1, wherein a first electrical connector is provided on a surface of the second component away from the first plastic encapsulating body, the second plastic encapsulating body covers the first electrical connector, and each of the plurality of second conductive structures is electrically connected to the second component through the first electrical connector.

7. The packaging structure according to claim 6, further comprising a protective cover installed on a surface of the second plastic encapsulating body away from the first plastic encapsulating body.

8. A preparing method of a packaging structure, comprising:
forming a first component and a first plastic encapsulating body on a carrier board, wherein the first component is embedded in the first plastic encapsulating body, and the first plastic encapsulating body comprises a first surface and a second surface opposite to each other;
defining a plurality of first channels in the first plastic encapsulating body, an end of each of the plurality of first channels extending to the first component;
forming a first conductive structure in each of the plurality of first channels, a portion of the first conductive structure exposed from the second surface and electrically connected to the first component;
forming a second plastic encapsulating body on the first plastic encapsulating body, wherein a second component is embedded in the second plastic encapsulating body, and the second plastic encapsulating body comprises a third surface facing the second surface and a fourth surface opposite to the third surface;
defining a plurality of second channels in the second plastic encapsulating body, an end of each of the plurality of second channels extending to the second component;
forming a second conductive structure in each of the plurality of second channels, wherein a portion of the second conductive structure is exposed from the third surface and electrically connected to the portion of the first conductive structure exposed from the second surface, another portion of the second conductive structure is exposed from the fourth surface and electrically connected to the second component, such that the first component and the second component are electrically connected to each other through the first conductive structure and the second conductive structure; and
removing the carrier board to obtain the packaging structure.

9. The preparing method according to claim 8, wherein forming the first conductive structure in each of the plurality of first channels comprises:
filling a conductive material in each of the plurality of first channels, and solidifying the conductive material to form the first conductive structure.

10. The preparing method according to claim 9, wherein the conductive material comprises at least one of a conductive ink and a conductive paste.

11. The preparing method according to claim 8, wherein forming the first component and the first plastic encapsulating body on the carrier board comprises:
forming the first component on the carrier board, and forming a first plastic preform on the carrier board, and the first plastic preform surrounding a sidewall of the first component;
solidifying the first plastic preform to obtain a first block;
defining a plurality of first holes in the first block, and forming a first conductive portion in each of the plurality of first holes, wherein each of the plurality of first holes extends through the first block;
forming a second block on the first block and the first component, wherein the first block and the second block constitute the first plastic encapsulating body;
defining a plurality of first trenches in the second block and forming a second conductive portion in each of the plurality of first trenches, wherein the plurality of first holes and the plurality of first trenches constitute the plurality of first channels, and the first conductive portion and the second conductive portion are electrically connected to form the first conductive structure.

12. The preparing method according to claim 9, wherein before removing the carrier board, the preparing method further comprises:
forming a third component and a lower plastic block on the first plastic encapsulating body, wherein the lower plastic block defines a plurality of second holes;
filling a conductive material in each of the plurality of second holes to form a third conductive portion, wherein the third conductive portion is electrically connected to the first conductive structure;
forming a second component and an upper plastic block on a support plate, wherein the third component is embedded in the upper plastic block;
defining a plurality of connecting channels in the upper plastic block, and filling a conductive material in each of the plurality of connecting channels to form a fourth conductive portion, wherein the fourth conductive portion is electrically connected to the second component;
removing the support plate to obtain an intermediate body; and
placing the upper plastic block of the intermediate body on the lower plastic block, wherein the lower plastic block and the upper plastic block constitute the second plastic encapsulating body, and the third conductive portion and the fourth conductive portion are electrically connected to each other to form the second conductive structure.

13. The preparing method according to claim 12, further comprising:
forming an adhesive layer between the lower plastic block and the upper plastic block.

14. The preparing method according to claim 9, wherein after removing the carrier board, the preparing method further comprises:
forming a dielectric layer on a surface of the first plastic encapsulating body away from the second plastic encapsulating body, wherein the dielectric layer defines a plurality of third channels;
filling a conductive material in each of the plurality of third channels to form a third conductive structure; and
forming a solder ball on the dielectric layer, wherein the solder ball is electrically connected to the third conductive structure.

15. The preparing method according to claim 8, wherein a first electrical connector is provided on a surface of the second component away from the first plastic encapsulating body, and after forming the second plastic encapsulating body on the first plastic encapsulating body, the second plastic encapsulating body further covers the first electrical connector.

16. The preparing method according to claim 15, wherein embedding the second component in the second plastic encapsulating body comprises:
installing the second component on the first plastic encapsulating body and forming a second plastic preform on the first plastic encapsulating body, wherein the second plastic preform covers the first electrical connector; and
solidifying the second plastic preform to obtain the second plastic encapsulating body.

17. The preparing method according to claim 15, further comprising:
forming a protective cover on a surface of the second plastic encapsulating body away from the first plastic encapsulating body.
